(19) United States
(12) Patent Application Publication
(10) Pub. No.: US 2024/0304575 A1
(43) Pub. Date: Sep. 12, 2024

(54) BONDING STRUCTURE FOR CONNECTING A CHIP AND A METAL MATERIAL AND MANUFACTURING METHOD THEREOF

(71) Applicant: TONG HSING ELECTRONIC INDUSTRIES, LTD., Taipei City (TW)

(72) Inventors: ZZU-CHI CHIU, Taipei City (TW); WEI-CHUNG CHAO, Taipei City (TW); YAN-WEI CHEN, Taipei City (TW)

(21) Appl. No.: 18/517,471

(22) Filed: Nov. 22, 2023

Related U.S. Application Data
(60) Provisional application No. 63/450,621, filed on Mar. 7, 2023.

(30) Foreign Application Priority Data
Sep. 7, 2023 (TW) 112133952

(51) Int. Cl. H01L 23/00

(52) U.S. Cl. CPC H01L 24/05; H01L 24/03; H01L 24/08; H01L 24/48; H01L 2224/0311; H01L 2224/0345; H01L 2224/03462; H01L 2224/05147; H01L 2224/05573; H01L 2224/05611; H01L 2224/05644; H01L 2224/08225; H01L 2224/48229; H01L 2924/2064

(57) ABSTRACT

A bonding structure for connecting a chip and a metal material, and a manufacturing method thereof are provided. The bonding structure includes a substrate, a chip, a metal member, at least one metal wire and an alloy connection layer. An upper surface of the substrate has a first metal pad and a second metal pad. The chip is disposed on the first metal pad. The metal member is disposed above the chip. The at least one metal wire has a first end and a second end, the first end is connected to an upper surface of the metal piece, and the second end is connected to the second metal pad. The alloy connection layer is connected between the metal member and the chip, and covers at least a part of a lower surface of the metal member.

### CROSS-REFERENCE TO RELATED PATENT APPLICATION

This application claims the benefit of priorities to Taiwan Patent Application No. 112133952, filed on Sep. 7, 2023, and the U.S. Provisional Patent Application Ser. No. 63/450,621, filed on Mar. 7, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a bonding structure and a manufacturing method thereof, and more particularly to a bonding structure for connecting a chip and a metal material and a manufacturing method thereof.

### BACKGROUND OF THE DISCLOSURE

With the development of electronic products, the requirement for the specification and density of chips inside the electronic products has gradually increased. In the related art, wire bonding is performed on aluminum pads during the chip packaging process. However, the existing chip packaging technology cannot meet high current density and service life requirements of high-power components. The high-power components usually operate with large currents, such that excessive wiring stress is generated in the chip, thereby easily leading to chip failure.

Therefore, how to overcome the above-mentioned problem through an improvement in structural design has become an important issue to be addressed in the related art.

### SUMMARY OF THE DISCLOSURE

In response to the above-referenced technical inadequacy, the present disclosure provides a bonding structure for connecting a chip and a metal material, and a manufacturing method thereof, so as to address an issue of the existing bonding structure of the chip not meeting high current density and service life requirements of high-power components.

In order to solve the above-mentioned problems, one of the technical aspects adopted by the present disclosure is to provide a bonding structure for connecting a chip and a metal material, which includes a substrate, a chip, a metal member, at least one metal wire, and an alloy connection layer. An upper surface of the substrate includes a first metal pad and a second metal pad. The chip is disposed on the first metal pad. The metal member is disposed above the chip. The at least one metal wire has a first end and a second end. The first end is connected to an upper surface of the metal member, and the second end is connected to the second metal pad. The alloy connection layer is connected between the metal member and the chip and covers at least a part of a lower surface of the metal member.

In order to solve the above-mentioned problems, another one of the technical aspects adopted by the present disclosure is to provide a method of manufacturing a bonding structure for connecting a chip and a metal material, which includes: placing a metal material onto a base layer; performing a lamination process to form a photoresist layer on an upper surface and a side surface of the metal material; performing a photolithography process to form a predetermined pattern on the photoresist layer; and forming an alloy connection layer on the upper surface of the metal material according to a shape of the predetermined pattern.

Therefore, in the bonding structure for connecting a chip and a metal material and the manufacturing method thereof provided by the present disclosure, by virtue of the alloy connection layer being connected between the metal member and the chip and covering at least a part of a lower surface of the metal member, a gold-tin (Au—Sn) layer structure is formed on the surface of the metal member. By the metal member being plated with the alloy connection layer to be a buffer pad, and performing a wire bonding process on the metal member, the overall cost can be lowered and the subsequent assembly process can achieve high reliability.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a bonding structure according to a first embodiment of the present disclosure;

FIG. 2 is a schematic top view of the bonding structure according to the first embodiment of the present disclosure;

FIG. 3 is a schematic top view of a bonding structure according to a second embodiment of the present disclosure;

FIG. 4 is a schematic side view of a bonding structure according to a third embodiment of the present disclosure;

FIG. 5 is a schematic side view of a bonding structure according to a fourth embodiment of the present disclosure;

FIG. 6 is a schematic side view of a bonding structure according to a fifth embodiment of the present disclosure;

FIG. 7 to FIG. 11 are schematic views of steps of a first manufacturing method of a bonding structure according to the present disclosure;

FIG. 12 to FIG. 15 are schematic views of steps of a second manufacturing method of a bonding structure according to the present disclosure;

FIG. 16 is a flowchart of step S11 to step S17 of a manufacturing method of a bonding structure according to the present disclosure;

FIG. 17 is a flowchart of step S171 to step S177 of the manufacturing method of the bonding structure according to the present disclosure; and

FIG. 18 is a flowchart of step S170 to step S176 of the manufacturing method of the bonding structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

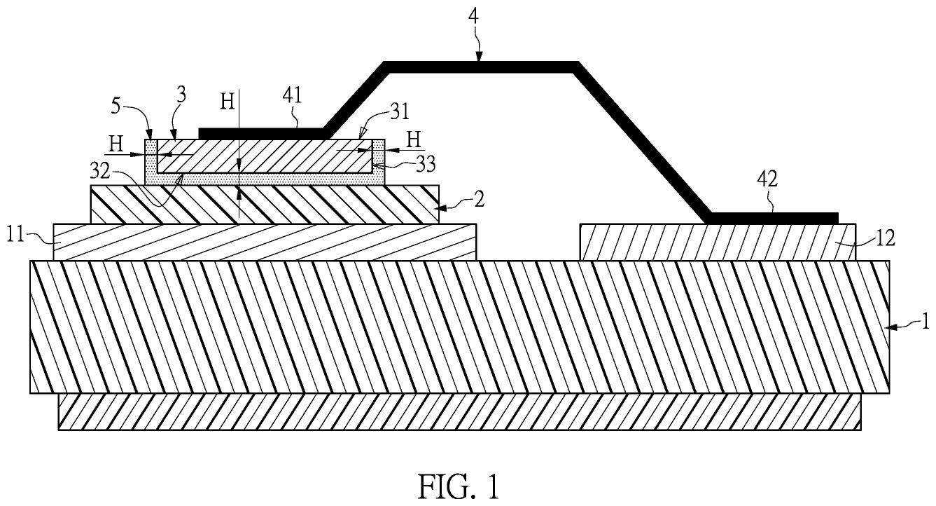

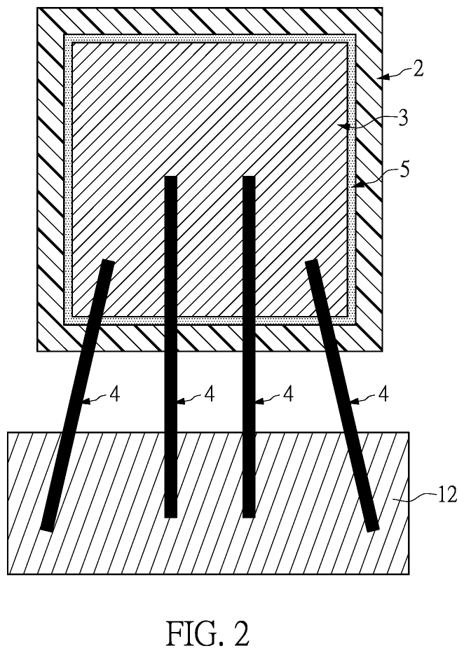

Referring to FIG. 1 and FIG. 2, FIG. 1 is a schematic side view of a bonding structure according to a first embodiment of the present disclosure, and FIG. 2 is a schematic top view of the bonding structure according to the first embodiment of the present disclosure. The present disclosure provides a bonding structure, which includes a substrate 1, a chip 2, a metal member 3, and at least one metal wire 4, and an alloy connection layer 5. An upper surface of the substrate 1 includes a first metal pad 11 and a second metal pad 12. The chip is disposed on the first metal pad 11. The metal member 3 is disposed above the chip 2. Specifically, the metal member 3 is disposed on a wire bonding region of the chip 2. The at least one metal wire 4 has a first end 41 and a second end 42. The first end 41 is connected to an upper surface 31 of the metal member 3, and the second end 42 is connected to the second metal pad 12. The at least one metal wire 4 can be formed by forward bonding or reverse bonding, and is not limited in the present disclosure. In addition, a quantity of the at least one metal wire 4 is not limited in the present disclosure. As shown in FIG. 2, a plurality of metal wires 4 are connected to the metal member 3 and the second metal pad 12. For the convenience of explanation, FIG. 2 only shows a part of the substrate 1, that is, the second metal pad 12. The alloy connection layer 5 is connected between the metal member 3 and the chip 2 and covers at least a part of a lower surface 32 of the metal member 3.

For example, the substrate 1 can be a ceramic substrate, and the chip 2 is a die which is formed by cutting a wafer. The metal member 3 is a copper block which is formed by cutting a copper foil. Furthermore, the metal member 3 is a copper block pattern formed by etching on an entire surface of the copper foil. A width of the copper block pattern is at least greater than a thickness of the copper block. Preferably, a ratio of the width of the copper block pattern to the thickness of the copper block is higher than 1 to 1. In addition, the alloy connection layer 5 is made of Au—Sn alloy. The alloy connection layer 5 is plated on the surface of the metal member 3 by electroplating or plasma evaporation (E-Gun). For example, a thickness of the alloy connection layer 5 (i.e., the Au—Sn alloy) ranges between 5 μm and 8 μm, and a thickness of the metal member 3 (i.e., the copper block) ranges between 30 μm and 40 μm.

In the present disclosure, the Au—Sn alloy is plated on the surface of the copper block through electroplating or plasma evaporation, such that an Au—Sn layer structure is formed on the surface of the copper block. Furthermore, the metal member 3 is plated with the alloy connection layer 5 to be a buffer pad, and the metal member 3 can be applied to the wire bonding region of the chip 2 by diffusion soldering, laser assisted bonding and thermal compression bonding. Because of high tensile strength and bonding strength of the Au—Sn alloy, the stability of the bonded structure can be improved.

The quantity and size of the metal member 3 can be appropriately adjusted according to an adhering region on the surface of the chip 2. As shown in FIGS. 1 and 2, the alloy connection layer 5 completely covers the lower surface 32 of the metal member 3, and the alloy connection layer 5 further covers a side surface 33 of the metal member 3. Moreover, portions of the alloy connection layer 5 which are located on the lower surface 32 and the side surface 33 of the metal member 3 have a same thickness H, and the thickness H ranges from 5 μm to 8 μm.

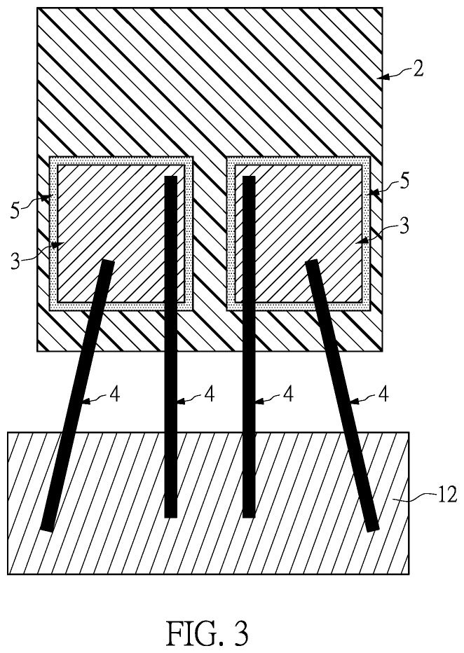

Referring to FIG. 3, FIG. 3 is a schematic top view of a bonding structure according to a second embodiment of the present disclosure. The bonding structure can include two metal members 3 that are separated from each other. The two metal members 3 are disposed on the surface of the chip 2, and both of the lower surface 32 and the side surface 33 of the two metal members 3 are covered by the alloy connection layer 5.

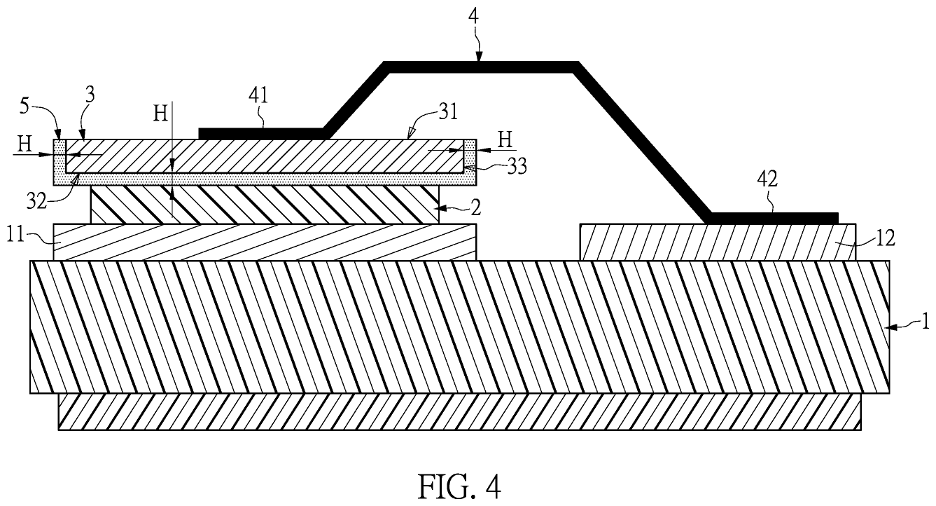

In FIG. 3, some of the plurality of metal wires 4 are connected to one of the two metal members 3, and others are connected to the other of the two metal members 3 and the second metal pad 12. In addition, referring to FIG. 4, FIG. 4 is a schematic side view of a bonding structure according to a third embodiment of the present disclosure. Comparing FIG. 1 with FIG. 4, the size of the metal member 3 in FIG. 4 is greater than the size of the chip 2. Specifically, in FIG. 4, an orthogonal projection of the metal member 3 that is projected onto the first metal pad 11 is larger than an orthogonal projection of the chip 2 that is projected onto the first metal pad 11.

It should be noted that in the first embodiment shown in FIGS. 1 and 2, the second embodiment shown in FIG. 3, and the third embodiment shown in FIG. 4, the alloy connection layer 5 is completely plated on the lower surface 32 and the side surface 33 of the metal member 3 through non-selective plating.

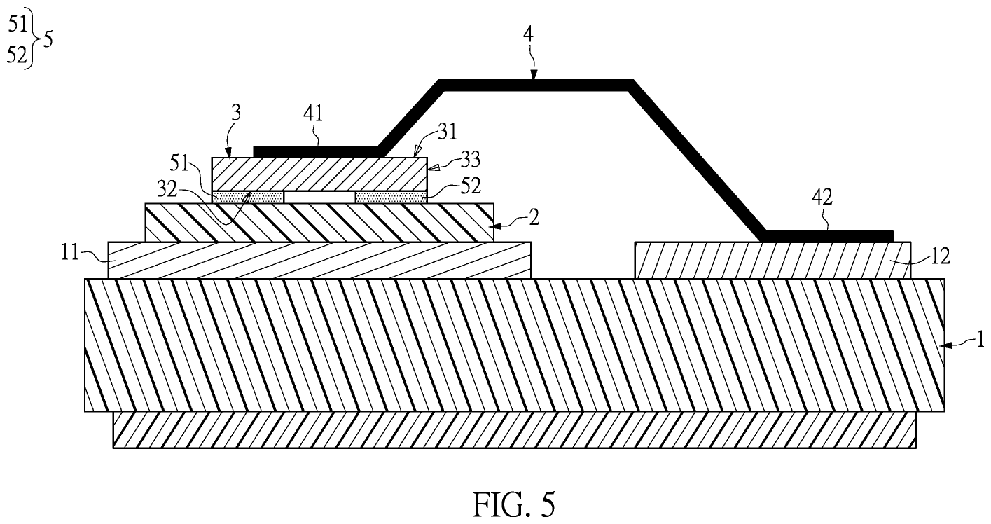

In addition, the size of the alloy connection layer 5 can be appropriately adjusted according to the adhering region on the surface of the chip 2. Furthermore, the alloy connection layer 5 can be selectively plated on a position on the surfaces of the metal member 3 corresponding to the adhering region on the surface of the chip 2. Referring to FIG. 5, FIG. 5 is a schematic side view of a bonding structure according to a fourth embodiment of the present disclosure. The alloy connection layer 5 further includes a plurality of alloy piece layers that are separated from each other, such as a first alloy piece layer 51 and a second alloy piece layer 52. As such, the alloy connection layer 5 can be arranged correspondingly according to a position of a signal terminal (not shown in the figures) of the chip 2 to increase the flexibility of the design.

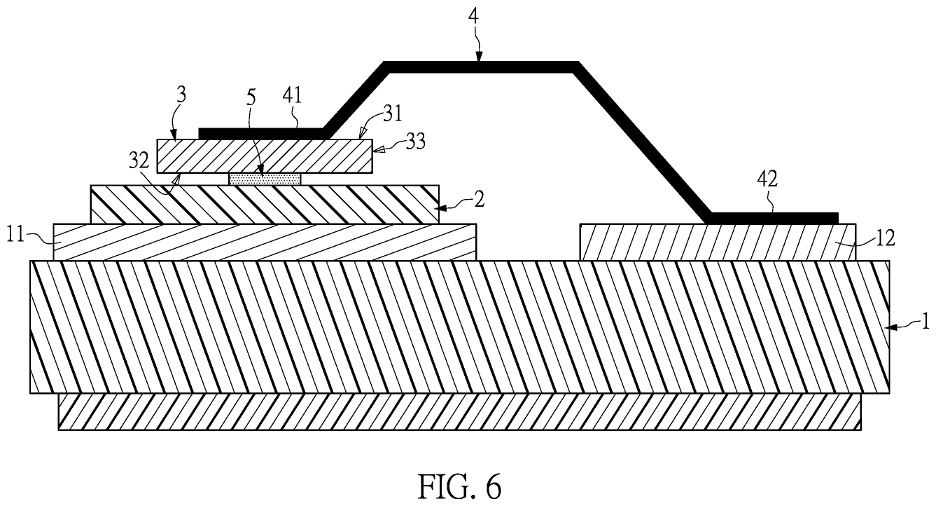

Referring to FIG. 6, FIG. 6 is a schematic side view of a bonding structure according to a fifth embodiment of the present disclosure. An orthogonal projection of the alloy connection layer 5 that is projected onto the first metal pad 11 is smaller than an orthogonal projection of the metal member 3 that is projected onto the first metal pad 11, that is, the size of the alloy connection layer 5 is smaller than that of the metal member 3. Furthermore, when the signal terminal of the chip 2 has a small opening but needs a thick copper wire for high-power applications, the alloy connection layer 5 can be disposed at the center of the lower surface 32 of the metal member 3, so as to easily adhere to the chip 2, and the upper surface of the chip 2 can have more space for wire bonding.

Therefore, in the fourth embodiment shown in FIG. 5 and the fifth embodiment shown in FIG. 6, the alloy connection layer 5 is selectively plated on the lower surface 32 of the metal member 3 through selective plating. However, the present disclosure is not limited thereto. For example, in the first embodiment shown in FIGS. 1 and 2, the second embodiment shown in FIG. 3, and the third embodiment shown in FIG. 4, the alloy connecting layer 5 can also be plated on the lower surface 32 of the metal member 3 through selective plating. In the fourth embodiment shown in FIG. 5 and the fifth embodiment shown in FIG. 6, the alloy connection layer 5 can also be completely plated on the lower surface 32 and the side surface 33 of the metal member 3 through non-selective plating.

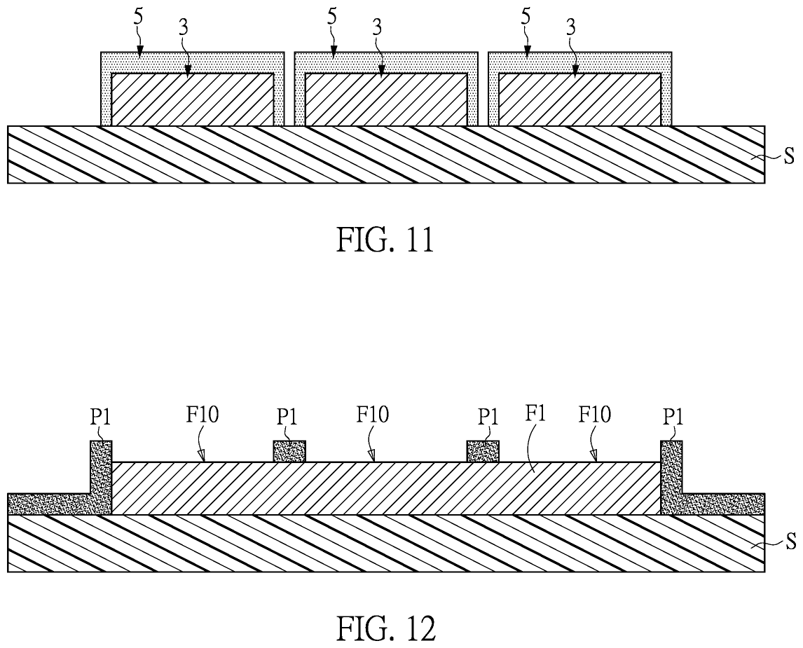

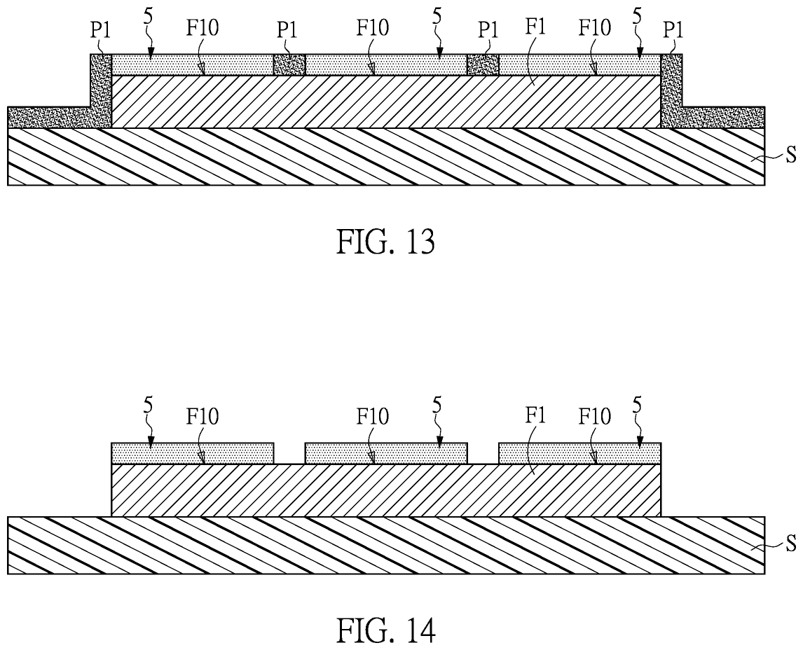

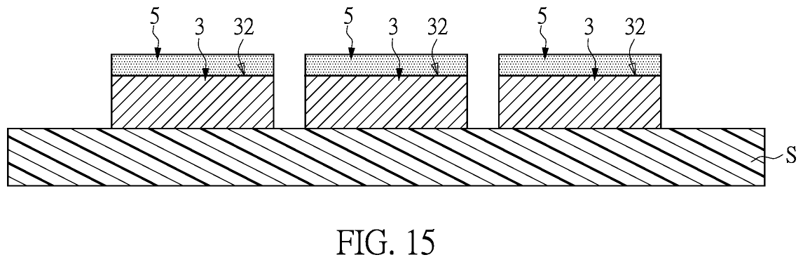

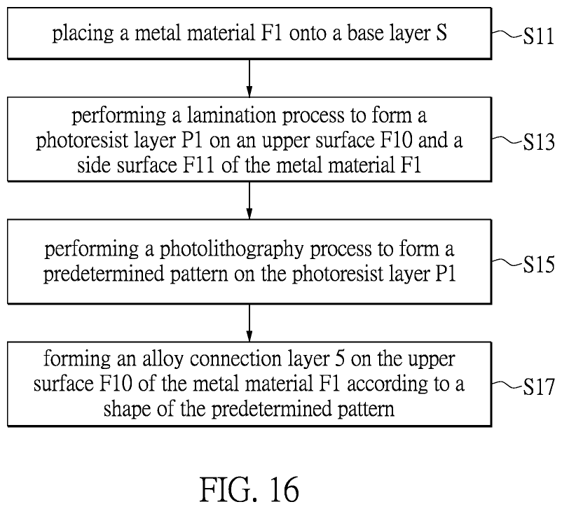

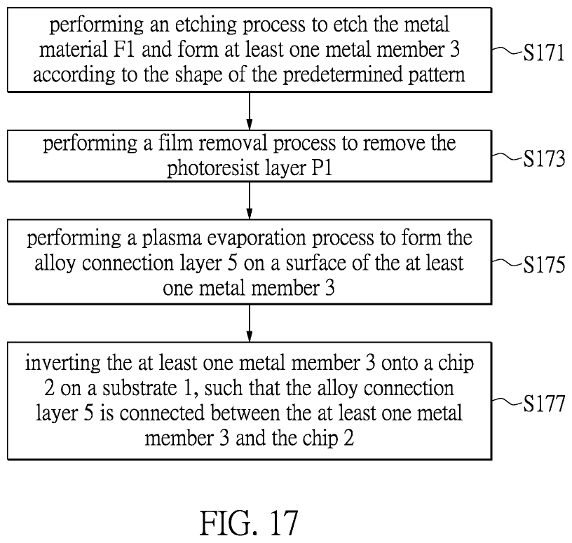

The present disclosure provides a method of manufacturing a bonding structure, which is applicable to the bonding structure of any implementation in the aforementioned first embodiment to the fifth embodiment. Referring to FIG. 7 to FIG. 11, and FIG. 7 to FIG. 16 in conjunction with FIG. 17, FIG. 7 to FIG. 11 are schematic views of steps of a first manufacturing method of a bonding structure according to the present disclosure, FIG. 16 is a flowchart of step S11 to step S17 of a manufacturing method of a bonding structure according to the present disclosure, and FIG. 17 is a flowchart of step S171 to step S177 of the manufacturing method of the bonding structure according to the present disclosure. The manufacturing method at least includes the following steps.
Step S11: placing a metal material F1 onto a base layer S.
Step S13: performing a lamination process to form a photoresist layer P1 on an upper surface F10 and a side surface F11 of the metal material F1.
   Step S15: performing a photolithography process to form a predetermined pattern on the photoresist layer P1.
   Step S17: forming an alloy connection layer 5 on the upper surface F10 of the metal material F1 according to a shape of the predetermined pattern.

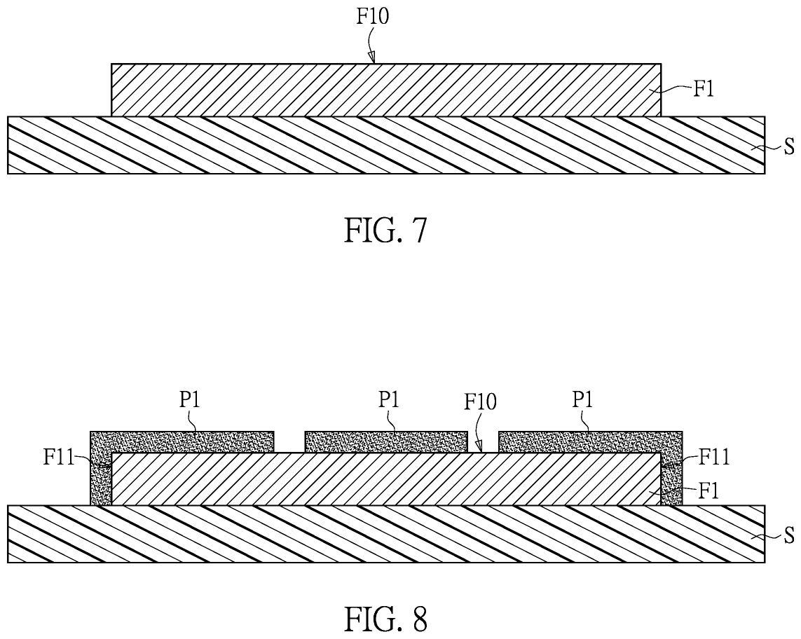

Regarding step S11, step S13, and step S15, as shown in FIGS. 7 and 8, the metal material F1 is disposed on the base layer S. For example, the base layer S can be a UV tape specifically used for cutting a wafer, which can be made of polyvinyl chloride (PVC) or polyethylene terephthalate (PET), but is not limited in the present disclosure. The metal material F1 can be a copper foil. The photoresist layer P1 is formed on the upper surface F10 and the side surface F11 of the metal material F1. The photoresist layer P1 which is formed by the lamination process can be a dry film photoresist. Then, a geometric pattern structure is further etched on the photoresist layer P1 through the photolithography process, which is the predetermined pattern described in step S15.

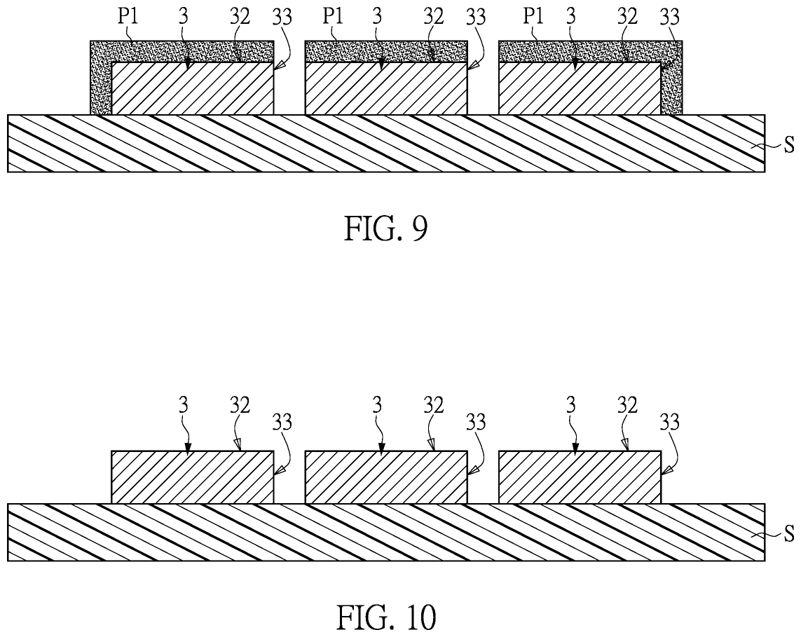

Regarding step S17, as shown in FIG. 9 to FIG. 11 in conjunction with FIG. 17, the process of forming the alloy connection layer 5 on the upper surface F10 of the metal material F1 according to the shape of the predetermined pattern (step S17) further includes:
Step S171: performing an etching process to etch the metal material F1 and form at least one metal member 3 according to the shape of the predetermined pattern.
Step S173: performing a film removal process to remove the photoresist layer P1.
Step S175: performing a plasma evaporation process to form the alloy connection layer 5 on a surface of the at least one metal member 3.
Step S177: inverting the at least one metal member 3 onto a chip 2 on a substrate 1, such that the alloy connection layer 5 is connected between the at least one metal member 3 and the chip 2.

Regarding step S171 to step S177, the metal material F1 (the copper foil) is etched through the etching process to transfer the shape of the predetermined pattern to the metal material F1. The etched metal material F1 forms at least one metal member 3 (the copper block). It should be noted that the at least one metal member 3 forms a copper block pattern according to the predetermined pattern. A width of the copper block pattern is at least greater than a thickness of the copper block. Preferably, a ratio of the width of the copper block pattern to the thickness of the copper block is higher than 1 to 1. The photoresist layer P1 is removed through a photoresist stripper, leaving only the metal member 3 which is located on the base layer S. Then, the alloy connection layer 5 is formed on the upper surface 32 and the side surface 33 of the metal member 3 through the plasma evaporation (i.e., E-Gun evaporation) process. After the alloy connection layer 5 is formed, the metal member 3 with the alloy connection layer 5 can be moved from the base layer S to the chip 2 on the substrate 1, and the alloy connection layer 5 is inverted and connected between the metal member 3 and the chip 2.

Therefore, the first manufacturing method shown in FIG. 7 to FIG. 11 refers to cutting copper foil to form the copper block pattern and then plating the alloy connection layer 5 on the surface including the side surface of the copper block.

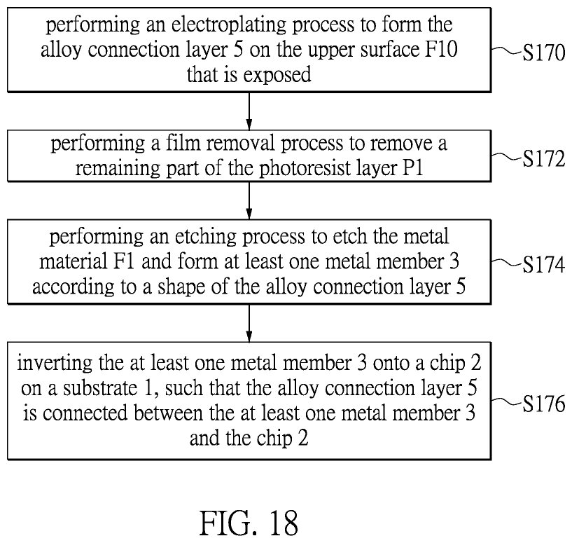

The present disclosure provides another method of manufacturing a bonding structure, which is applicable to the bonding structure of any implementation in the aforementioned fourth embodiment to the fifth embodiment. Referring to FIG. 12 to FIG. 15 in conjunction with FIG. 18, FIG. 12 to FIG. 15 are schematic views of steps of a second manufacturing method of a bonding structure according to the present disclosure, and FIG. 18 is a flowchart of step S170 to step S176 of the manufacturing method of the bonding structure according to the present disclosure. Comparing the second manufacturing method with the first manufacturing method, the main difference is as follows: the specific detail of step S17 of the second manufacturing method is different. As shown in FIG. 12, in the second manufacturing method, a part of the photoresist layer P1 is removed after performing the photolithography process, such that a part of the upper surface F10 of the metal material F1 is exposed. Moreover, the process of forming the alloy connection layer 5 on the upper surface F10 of the metal material F1 according to the shape of the predetermined pattern further includes (step S17):
Step S170: performing an electroplating process to form the alloy connection layer 5 on the upper surface F10 that is exposed.
Step S172: performing a film removal process to remove a remaining part of the photoresist layer P1.
Step S174: performing an etching process to etch the metal material F1 and form at least one metal member 3 according to a shape of the alloy connection layer 5.
Step S176: inverting the at least one metal member 3 onto a chip 2 on a substrate 1, such that the alloy connection layer 5 is connected between the at least one metal member 3 and the chip 2.

Regarding step S170 to step S176, the alloy connection layer 5 is formed on the exposed upper surface F10 (i.e., the upper surface F10 that is not covered by the photoresist layer P1) through electroplating. The alloy connection layer 5 will be limited by the photoresist layer P1 and only be formed on the part of the upper surface F10 that is not covered by the photoresist layer P1. In other words, the alloy connecting layer 5 forms a predetermined pattern to achieve the effect of selective plating. The photoresist layer P1 is removed by the photoresist stripper, leaving only the metal member 3 which is located on the base layer S and the alloy connection layer 5 which is located on the metal member 3. Then, the metal material F1 is etched through the etching process.

The etched metal material F1 forms the at least one metal member 3, and the at least one metal member 3 forms the copper block pattern according to the predetermined pattern. The width of the copper block pattern is at least greater than the thickness of the copper block. Preferably, the ratio of the width of the copper block pattern to the thickness of the copper block is higher than 1 to 1. Afterwards, the at least one metal member 3 with the alloy connection layer 5 can be moved from the base layer S to the chip 2 on the substrate 1, and the alloy connection layer 5 is inverted and connected between the at least one metal member 3 and the chip 2.

Therefore, the second manufacturing method shown in FIG. 12 to FIG. 15 refers to plating the alloy connection layer 5 on the surface of the un-etched copper foil and then performing the etching process. Comparing the second manufacturing method with the first manufacturing method, the alloy connection layer 5 formed by the second manufacturing method will not be formed on the side surface of the copper block, but only on the upper surface of the copper block because sequences of the formation of the Au—Sn plating layer and the etching of the copper foil are different.

### Beneficial Effects of the Embodiments

In conclusion, in the bonding structure for connecting a chip and a metal material and the manufacturing method thereof provided by the present disclosure, by virtue of the alloy connection layer being connected between the metal member and the chip and covering at least a part of a lower surface of the metal member, a gold-tin (Au—Sn) layer structure is formed on the surface of the metal member. By the metal member 3 being plated with the alloy connection layer 5 to be a buffer pad, and performing a wire bonding process on the metal member 3, the overall cost can be lowered and the subsequent assembly process can achieve high reliability.

Moreover, in the present disclosure, the Au—Sn alloy is plated on the surface of the copper block through electroplating or plasma evaporation, such that an Au—Sn layer structure which is used as an adhering layer is formed on the surface of the copper block. The metal member 3 is plated with the alloy connection layer 5 to be a buffer pad, and the metal member 3 can be applied to the wire bonding region of the chip 2 by diffusion soldering, laser assisted bonding and thermal compression bonding. Because of high tensile strength and bonding strength of the Au—Sn alloy, the stability of the bonded structure can be improved. In addition, compared with the existing technology where the adhering layer is made of sintered silver, the adhering layer made of the Au—Sn alloy can effectively lower the costs of the material.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A bonding structure for connecting a chip and a metal material, comprising:
a substrate having an upper surface, wherein the upper surface includes a first metal pad and a second metal pad;
a chip disposed on the first metal pad;
a metal member disposed above the chip;
at least one metal wire having a first end and a second end, wherein the first end is connected to an upper surface of the metal member, and the second end is connected to the second metal pad; and
an alloy connection layer connected between the metal member and the chip, and covering at least a part of a lower surface of the metal member.

2. The bonding structure according to claim 1, wherein the alloy connection layer is made of Au—Sn alloy, and the metal member is made of a copper foil.

3. The bonding structure according to claim 2, wherein the alloy connection layer is made by electroplating or plasma evaporation.

4. The bonding structure according to claim 2, wherein a thickness of the alloy connection layer ranges between 3 μm and 5 μm.

5. The bonding structure according to claim 1, wherein the alloy connection layer is located at the center of the lower surface of the metal member, and an orthogonal projection of the alloy connection layer that is projected onto the first metal pad is smaller than an orthogonal projection of the metal member that is projected on to the first metal pad.

6. The bonding structure according to claim 1, wherein the alloy connection layer includes a plurality of alloy piece layers that are separated from each other, and the plurality of alloy piece layers are distributed on the lower surface of the metal member.

7. The bonding structure according to claim 1, wherein the alloy connection layer further completely covers a side surface and the lower surface of the metal member.

8. The bonding structure according to claim 1, wherein an orthogonal projection of the metal member that is projected onto the first metal pad is larger than an orthogonal projection of the chip that is projected onto the first metal pad.

9. A method of manufacturing a bonding structure for connecting a chip and a metal material, comprising:
placing a metal material onto a base layer;
performing a lamination process to form a photoresist layer on an upper surface and a side surface of the metal material;
performing a photolithography process to form a predetermined pattern on the photoresist layer; and
forming an alloy connection layer on the upper surface of the metal material according to a shape of the predetermined pattern.

10. The method according to claim 9, wherein the process of forming the alloy connection layer on the upper surface of the metal material according to the shape of the predetermined pattern further includes:
performing an etching process to etch the metal material and form at least one metal member according to the shape of the predetermined pattern;
performing a film removal process to remove the photoresist layer;
performing a plasma evaporation process to form the alloy connection layer on a surface of the at least one metal member; and
inverting the at least one metal member onto a chip on a substrate, such that the alloy connection layer is connected between the at least one metal member and the chip.

11. The method according to claim 9, wherein a part of the photoresist layer is removed after the photolithography process is performed, such that a part of the upper surface of the metal material is exposed; wherein the process of forming the alloy connection layer on the upper surface of the metal material according to the shape of the predetermined pattern further includes:
performing an electroplating process to form the alloy connection layer on the upper surface that is exposed;
performing a film removal process to remove a remaining part of the photoresist layer;
performing an etching process to etch the metal material and form at least one metal member according to a shape of the alloy connection layer; and
inverting the at least one metal member onto a chip on a substrate, such that the alloy connection layer is connected between the at least one metal member and the chip.

12. The method according to claim 9, wherein an upper surface of the substrate includes a first metal pad and a second metal pad, and the chip is disposed on the first metal pad.

13. The method according to claim 12, further comprising:
providing at least one metal wire to connect the at least one metal member and the second metal pad.

14. The method according to claim 13, wherein the alloy connection layer is made of Au—Sn alloy, and a thickness of the alloy connection layer ranges between 3 μm and 5 μm.

15. The method according to claim 13, wherein the alloy connection layer is located on the lower surface of the metal member, and an orthogonal projection of the alloy connection layer that is projected onto the first metal pad is smaller than an orthogonal projection of the metal member that is projected onto the first metal pad.

16. The method according to claim 13, wherein the alloy connection layer includes a plurality of alloy piece layers that are separated from each other, and the plurality of alloy piece layers are distributed on the lower surface of the metal member.

17. The method according to claim 13, wherein the alloy connection layer further completely covers a side surface and the lower surface of the metal member.

18. The method according to claim 12, wherein an orthogonal projection of the metal member that is projected onto the first metal pad is larger than an orthogonal projection of the chip that is projected onto the first metal pad.
